(19) United States
(12) Patent Application Publication
(10) Pub. No.: US 2024/0201284 A1
(43) Pub. Date: Jun. 20, 2024

(54) PROCESS FOR DETECTING AGEING OF A DC BUS CAPACITOR OF A POWER CONVERTER

(71) Applicant: Schneider Toshiba Inverter Europe SAS, Pacy sur Eure (FR)

(72) Inventors: Alain Dutrey, Fontaine-sous-Jouy (FR); Mohamad Koteich, Vernon (FR)

(73) Assignee: Schneider Toshiba Inverter Europe SAS, Pacy sur Eure (FR)

(21) Appl. No.: 18/534,897

(22) Filed: Dec. 11, 2023

(30) Foreign Application Priority Data
Dec. 15, 2022 (EP) 22306890.9

(51) Int. Cl. G01R 31/64

(52) U.S. Cl. CPC G01R 31/64

(57) ABSTRACT

A method to estimate a remaining of useful life of a DC link capacitor of a converter through determination of a minimum value Cₗᵢₘ of its capacitance C under which performances of the converter are considered as insufficient. The method includes implementing a real time model including a motor drive model and a capacitor model using decreasing capacitor values to calculate a forecasted minimum capacitance Cₗᵢₘ sufficient for keeping at least one of DC voltage ripple, motor current ripple, speed ripple or torque ripple under a specified value. The method further includes calculating a time difference between a time T_{actual}, for which the capacitor has an estimated capacitance based on an ageing curve C_{curve}, and a time Tₗᵢₘ for which the capacitor will have the forecasted minimum capacitance Cₗᵢₘ, with the use of an ageing curve C_{curve} of the capacitor and estimating the remaining useful life of the capacitor T_{actual}-Tₗᵢₘ.

### FIELD OF THE DISCLOSURE

The present disclosure concerns maintenance of power converters and equipment such as motors and pumps powered by such power converters and provides an estimation of Remaining Useful Life (hereafter also named RUL) of a power converter having a DC Bus capacitor based on measuring the ageing of such capacitor during the life of said converter.

### BACKGROUND

DC Bus capacitors are key functional components of DC link power converters, but they also are a major cause of failure due to their ageing sensitivity to operational voltage and temperature. Ageing capacitors have their capacitance decreasing with time and their equivalent serial resistance (hereafter ESR) increasing with time. Empirical models are used to estimate capacitor lifetime, using measured voltage and temperature as input. By taking operational context as an input and using generic models a prediction of potential end of life defined as critical failure of the capacitor may be furnished. However, this feed forward approach does not anticipate drifts caused by aged capacitors due to ageing models precision errors. In consequence, DC link applications where the DC link capacitor is aged may become unstable before an end of life event of the converter is predicted. In consequence, such ageing capacitors may create current and voltages ripples that degrade the operation of the devices powered by the power converters before the capacitors reach their full failure mode which is open or closed circuit.

### SUMMARY OF THE INVENTION

In view of such context, the present disclosure concerns a method to estimate a remaining of useful life of a DC link capacitor of a converter through determination of a minimum value Cₗᵢₘ of its capacitance C under which performances of the converter are considered as insufficient comprising:
implementing a real time model (130, 230) comprising a motor drive model and a capacitor model using decreasing capacitor values (140, 150, 240, 250) to calculate a forecasted minimum capacitance Cₗᵢₘ sufficient for keeping at least one of DC voltage ripple, motor current ripple, speed ripple or torque ripple under a specified value;
calculating a time difference between a time T_{actual}, for which the capacitor has an estimated capacitance based on an ageing curve C_{curve}, and a time Tₗᵢₘ for which the capacitor will have the forecasted minimum capacitance Cₗᵢₘ, with the use of an ageing curve C_{curve} of said capacitor and estimating the remaining useful life of said capacitor T_{actual}-Tₗᵢₘ.

In embodiment which may be alternate or combined:

The method may comprise initializing said ageing curve through capacitance calculation of estimated values of said DC link capacitor during an initialization phase to provide an initial part of said ageing curve C_{curve} and calculating a remainder of said ageing curve C_{curve} using ageing characteristics of said capacitor.

Said capacitance calculation may comprise:
measuring of a voltage v_{src} and a current i_{src} at a voltage source upstream of the DC link capacitor;
measuring a voltage v_{dc} downstream from said DC link capacitor and either measuring a current i_{dc} or measuring an output power Pₒᵤₜ and calculating an input power P_{dc}, which is equal to an output power Pₒᵤₜ plus converter losses Pₗₒₛₛ, downstream from said DC link capacitor;
calculating an estimation of a capacitance value Ĉ of said capacitor based on said voltage v_{dc} downstream from said DC link capacitor, current i_{dc} or input power P_{dc}; Preferably, Pₗₒₛₛ is identified through a known function Pₗₒₛₛ=f(Pₒᵤₜ).

In a preferred embodiment, said motor drive model comprises performance criterion Pc, including, but not limited to, dc voltage oscillation amplitude and motor control quality and wherein said motor drive model is simulated for different system conditions, system parameters and system input power supply and load to evaluate such performance criterion continuously according to decreasing capacitance values and define said minimum acceptable capacitance Cₗᵢₘ.

Said different conditions may comprise grid impedance values R_{dc}, L_{dc} which are pre-defined in the drive model or predefined by the user and based on the application load profile and history.

Said different conditions may also comprise grid impedance R_{dc}, L_{dc}, corresponding to a usual loading or grid impedance R_{dc}, L_{dc} of a worst-case scenario, with maximum rated grid impedance and maximum loading.

The method may comprise further:
calculating an ESR of said DC link capacitor based on said measurements,
implementing a modified motor drive model and capacitor model considering said ESR of said DC link capacitor to calculate the minimum capacitance Cₗᵢₘ and the minimum ESR ESRₗᵢₘ allowing controlled system stability, and,
determining an ESR curve ESR_{curve} of said capacitor,
calculating (220) the time difference between the actual capacitance and the forecasted minimum capacitance Cₗᵢₘ together with the difference between the actual ESR and the forecasted minimum ESR ESRₗᵢₘ, to estimate the remaining useful life of said capacitor considering the first occurrence of one of said minimum capacitance and minimum ESR.

Said ageing curve C_{curve} may be based on a capacitor ageing model of the form

$${C}_{a} ( t ) = {e}^{α t} + β$$

The method may also comprise further tracking a capacitance value C_{actual} through a capacitance observer activated during transient conditions of the operation of the converter.

The method may also comprise calculating temperature of said capacitor using a comparison of said capacitance value C_{actual} and a capacitor C_{ageing} resulting of the capacitor curve C_{curve} obtained after the curve initialization.

### BRIEF DESCRIPTION OF THE DRAWINGS

A detailed description of exemplary embodiments will be discussed hereunder in reference to the attached drawings where:

FIG. 1 shows a basic inverter circuit comprising a DC bus capacitor;

FIG. 2 shows a first embodiment of capacitor ageing determination process;

FIG. 3 shows a second embodiment of capacitor ageing determination process with ESR evaluation;

FIG. 4 shows a third embodiment of capacitor ageing determination process with temperature computation and additional capacitance observer means;

FIG. 5 shows a fourth embodiment of capacitor ageing determination process with temperature computation and capacitance observer means;

FIG. 6 shows a flowchart of a method of the disclosure.

### DETAILED DESCRIPTION OF EMBODIMENTS OF THE INVENTION

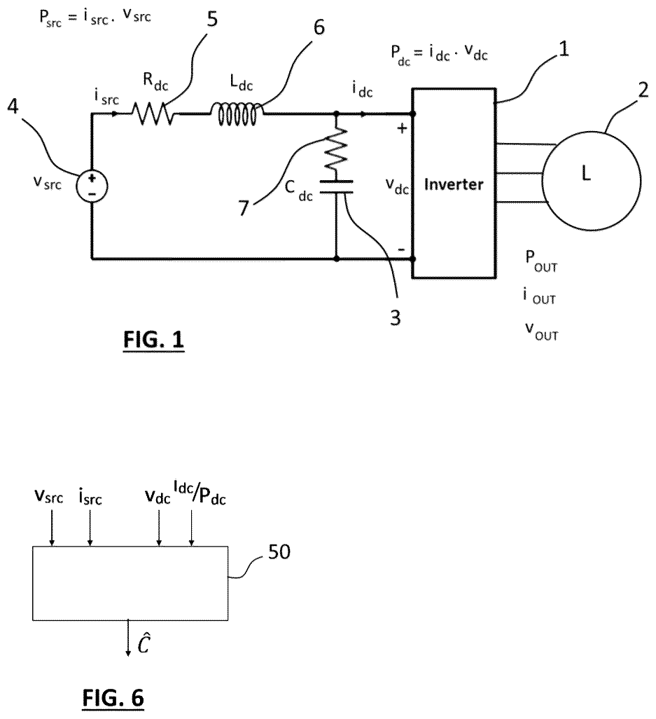

To estimate a remaining useful life (RUL) of a capacitor of a converter, such as a converter 1 driving a load 2 such as a motor, comprising a DC Link capacitor 3 having an ESR 7 as depicted in FIG. 1, the present disclosure provides measurements of the values of the capacitance C of the DC Link capacitor 3 and uses an embedded motor drive model implemented in a control module of the motor.

In order to evaluate the health of such a DC link capacitor, performance criteria may include DC voltage oscillation, DC voltage amplitude and motor control quality. In the present disclosure one or more of such criteria are implemented in the motor drive model. The model is implemented in real time in different conditions of a power supply 4 of the converter 1 in term of grid resistance R_{dc} 5 and grid self L_{dc} 6, and the selected performance criterion is evaluated continuously considering at least one of the following grid conditions which are the most relevant for the application:
Case 1: A realistic grid resistance R_{dc} 5 and grid self L_{dc} 6, with usual loading (e.g. based on the application load profile and history).
Case 2: A worst-case scenario, with maximum grid resistance R_{dc} 5 and grid self L_{dc} 6, (weak grid) and maximum load of the motor.

The grid conditions may be pre-defined in a control program of the converter, a control program of a remote survey system or defined in a case by case basis by the user.

The implementation of the model is performed in all cases for different values of capacitance of the capacitor 3 in order to simulate the behavior of the capacitor during its ageing e.g., by using the forecasted values in the ageing curves of the capacitor. When at least one of the performance criteria is violated in simulation, the corresponding value of the capacitance is recorded as a minimum value Cₗᵢₘ. This being done, the ageing curve is used to calculate the time difference between the actual capacitance point and the forecasted Cₗᵢₘ point, to estimate the RUL of such capacitor. When the model is implemented with case 1 data, the calculated RUL is considered as an estimated RUL. When the model is implemented with case 2 data, the calculated RUL is considered as a first RUL limit to provide a warning. One or both limits can be used to assess the RUL within the corresponding context (conservative worst-case or more realistic based on the application).

The load drive model can be a detailed model, or an equivalent simplified model. The granularity of the model will impact the precision of the RUL estimation.

In particular, introducing the equivalent serial resistance ESR of the capacitor allows to obtain a more accurate simulation and RUL calculation.

The present disclosure also provides a method to find the minimum value of capacitance of the DC link capacitor that guarantees good performance of the converter as Cₗᵢₘ may serve to provide a limit working capacitor value for such capacitor.

The present disclosure uses estimation of the capacitance and its parasitic resistance from input and/or output voltages and currents measurement and DC Bus voltage. In addition, a collection of empirical ageing functions allows to extrapolate the fitted estimated capacitance and estimate remaining useful life without knowledge of the temperature.

Since the capacitance vary locally according to the temperature, the temperature can be estimated by adding a local variation model to the calculated ageing model. Then capacitor stress, seen as the present ageing tendency is computed as a derivative of ageing fitting.

This, together with computing the minimum capacitance allowing controlled system stability, allows to predict the beginning of failure of the DC link power system due to capacitance reduction over time.

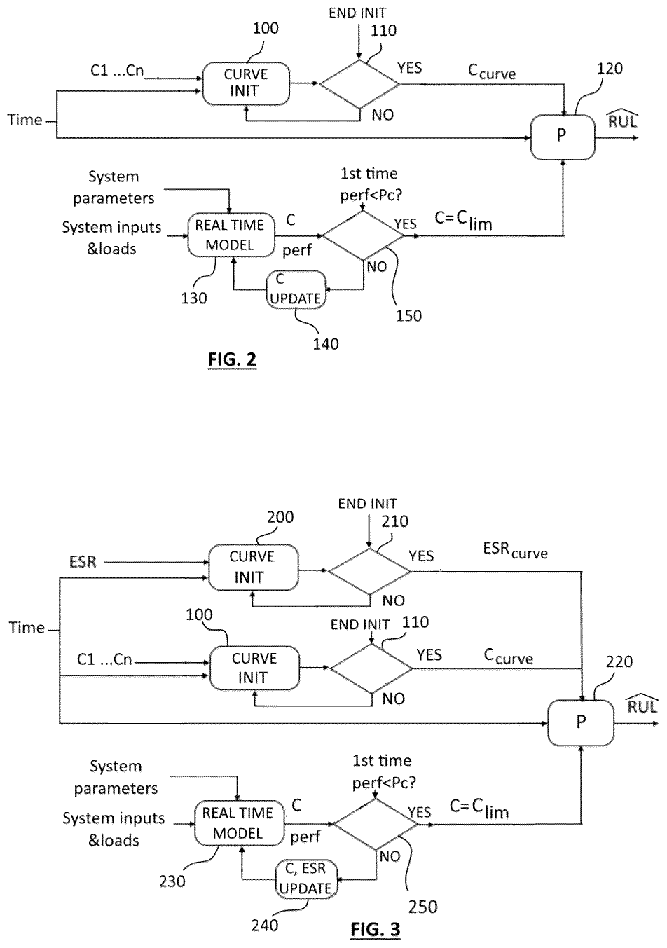

In FIG. 2 the upper part concerns the calculation of the capacitor curve C_{curve}. In this example measured capacitor values and time t are input in a curve initialization module 100 and the curve is initialized providing a resulting curve C_{curve} until an end of initialization 110 is reached.

The lower part of FIG. 2 concerns the computation of the lower capacitor value Cₗᵢₘ using the real time model 130 of the motor which is computed with different values of system parameters and system input and load in accordance with case 1 or case 2 above and for decreasing values of capacitance 140 for capacitor 3. The model outputs a performance which is compared to a performance criterion 150. Calculation with the model is reiterated with updated decreasing capacitor values 140. The first time the performance of the simulated motor drive model is under the selected criterion perf<Pc, the capacitance model 160 is implemented to obtain the limit lower value Cₗᵢₘ of C under which the capacitor is considered as too degraded to allow a correct operation of the converter.

Both the C_{curve} and the limit value Cₗᵢₘ are computed in a prognosis estimator 120 taking into account the current time to calculate the RUL of the capacitor.

In FIG. 3, the method takes into account the ESR of the capacitor 3 at the initialization phase where an ESR curve initialization 200 is done until an end 210 of the ESR curve initialization process is reached. The ESR curve ESR_{curve} is provided together with the capacitance curve C_{curve} to the prognosis estimator 220 receiving also the Cₗᵢₘ value calculated with an adapted real time model 230 taking into account C and ESR values. As in FIG. 2, the model is implemented with decreasing C values and increasing ESR values until the performances of the converter goes under specified performance criteria such as ripple, dc voltage oscillation amplitude and motor control quality which determines the Cₗᵢₘ value.

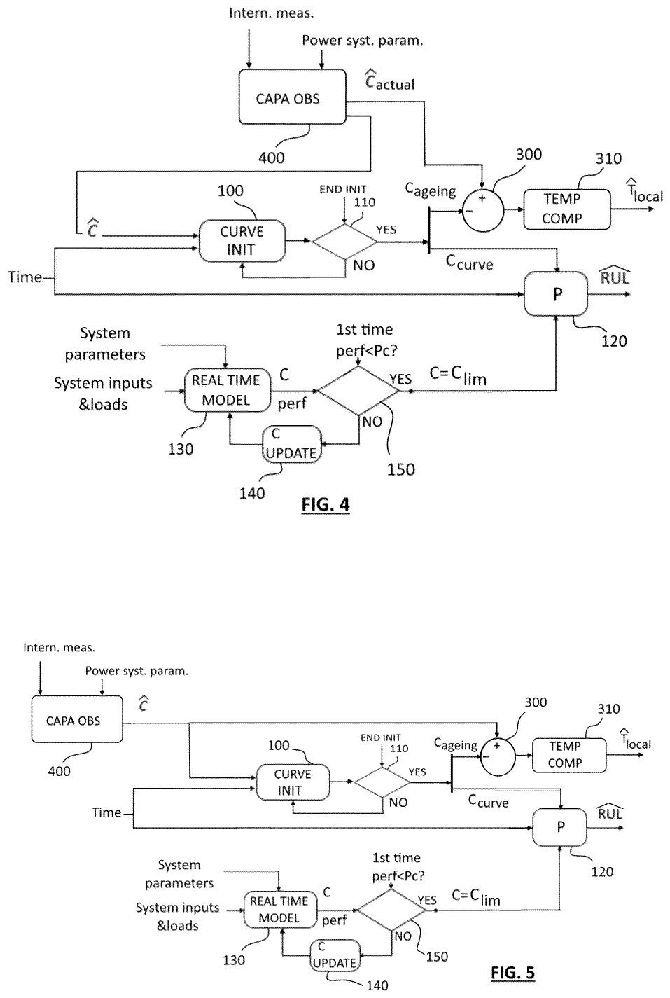

FIG. 4 concerns a realization mode based on the realization mode of FIG. 2 where a temperature measurement is added through comparing 300 an estimated capacitor value C_{actual} estimated through an observer module 400 together with the ageing capacitor value C_{ageing} calculated with the curve initialization module 100 in order to provide a delta signal to a temperature computation module 310.

The capacitor observer module 400 has as inputs the power system parameters and internal measurements of the converter device of FIG. 1 in order to calculate the estimated capacitor value C_{actual}.

In FIG. 5 the observer means 400 are used also for the capacitance curve initialization 100. This also permits to proceed to modifications of the curve during the life of the converter through renewed initialization processes.

The realizations modes of FIGS. 4 and 5 may also be based on the realization mode of FIG. 3 where the ESR is used to improve the [symbol] estimation.

In all the realization modes, the estimated remaining useful life [symbol] of the capacitor.

To summarize, the method to estimate a remaining of useful life of a DC link capacitor 3 of a converter 1 through determination of a minimum value of its capacitance Cₗᵢₘ under which performances of the converter are considered as insufficient comprises:
a. implementing a motor drive model 130, 230 using decreasing capacitor values 140, 150, 240, 250 and a capacitor model 160, 260 to calculate a forecasted minimum capacitance Cₗᵢₘ keeping at least one of DC voltage ripple, motor current ripple, speed ripple or torque ripple under a specified value;
b. calculating a time difference between a time T_{actual}, for which the capacitor has an actual capacitance determined by an ageing curve C_{curve}, and a time Tₗᵢₘ for which the capacitor will have the forecasted minimum capacitance Cₗᵢₘ, with the use of the ageing curve C_{curve} of said capacitor and estimating the remaining useful life of said capacitor T_{actual}-Tₗᵢₘ 120.

This method may be repeated periodically or at specific instances of the life of the converter to provide adapted RUL data according to the use of the converter.

The ageing curve may be obtained through measurements on said DC link capacitor during an initialization phase to provide an initial part of said ageing curve C_{curve}.

This may be done through measurement of a voltage v_{src} and a current i_{src} at a voltage source upstream of a DC link capacitor, measuring a voltage v_{dc} downstream from said DC link capacitor and either measuring a current i_{dc} or measuring an output power Pₒᵤₜ and calculating an input power P_{dc}, which is equal to the output power Pₒᵤₜ plus converter losses Pₗₒₛₛ, downstream from said DC link capacitor. Such measurements are input in a controller 50 having analog to digital converters and means to calculate an estimation of an actual capacitance Ĉ of said capacitor and calculating a remainder of said ageing curve C_{curve} using ageing characteristics of said capacitor which may be input according to manufacturer data.

In case, the output power Pₒᵤₜ is measured, the input power P_{dc} is calculated using a known function Pₗₒₛₛ=f(Pₒᵤₜ).

In order to initialize and calculate the capacitor ageing curve, the following traditional model (a) may be considered:

$${C}_{a} ( t ) = {e}^{α t} + β ( a )$$

In such case, such model can be expressed as a state model as follow:

$$\frac{{dC}_{a} ( t )}{dt} = α {C}_{a} ( t ) - α β$$

Differentiation expression allows to write such model under a recursive form:

$$\frac{{C}_{a} ( t ) - {C}_{a} ( t - Δ t )}{Δ t} = α {C}_{a} ( t - Δ t ) - α β$$

$${C}_{a} ( t ) = ( 1 + α Δ t ) {C}_{a} ( t - Δ t ) - α β Δ t$$

This provides the recursive expression:

$${C}_{a} ( n ) = ( 1 + αΔ t ) {C}_{a} ( n - 1 ) - αβΔ t$$

$${C}_{a} ( n ) = {C}_{a} ( n - 1 ) + αΔ {tC}_{a} ( n - 1 ) - αβΔ t$$

which allows to model the capacitor ageing recursively with a non-constant sampling.

For calculation, a recursive LMS (least mean square) algorithm may then be considered where parameters of the model (a) above are identified through calculation under matrix form:

$$r ( t ) = [ \begin{matrix}{r}_{1} \\ {r}_{2} \\ {r}_{3}\end{matrix} ] = [ \begin{matrix}{C}_{n - 1} \\ Δ t {C}_{n - 1} \\ - Δ t\end{matrix} ]$$

$$\hat{p} ( t + 1 ) = [ \begin{matrix}{\hat{p}}_{1} \\ {\hat{p}}_{2} \\ {\hat{p}}_{3}\end{matrix} ] = [ \begin{matrix}1 \\ α \\ α β\end{matrix} ]$$

$$k ( t + 1 ) = \frac{P ( t ) r ( t )}{1 + {r}^{T} ( t ) P ( t ) r ( t )}$$

$$P ( t + 1 ) = P ( t ) - k ( t + 1 ) {r}^{T} ( t ) P ( t )$$

$${\hat{y}}_{m} ( t + 1 ) = {r}^{T} ( t ) \hat{p} ( t )$$

$$\hat{p} ( t + 1 ) = \hat{p} ( t ) + k ( t + 1 ) [ {y}_{s} ( t + 1 ) - {\hat{y}}_{m} ( t + 1 ) ]$$

Where r^{T} is the transposed vector of vector r

With initialization of:

$$P ( {t}_{0} ) = [ \begin{matrix}{P}_{0} & 0 & 0 \\ 0 & {P}_{0} & 0 \\ 0 & 0 & {P}_{0}\end{matrix} ] with {P}_{0} >> 1$$

$$\hat{p} ( {t}_{0} ) = [ \begin{matrix}1 \\ {α}_{0} \\ {α}_{0} {β}_{0}\end{matrix} ]$$

with α₀ and β₀ identified from manufacturer ageing information, or accelerated ageing tests done on the capacitor 3. Such LMS algorithm allows to build an approximated C curve.

A recursive LMS with forgetting factor algorithm may also be used to build the curve and adapt such to working conditions of the converter:

In such algorithm is introduced a scalar forgetting factor λ to allow adaptation to a new ageing model due to changes in the operating conditions.

Calculations under matrix form allows to identify parameters of the model (a):

$$r ( t ) = [ \begin{matrix}{r}_{1} \\ {r}_{2} \\ {r}_{3}\end{matrix} ] = [ \begin{matrix}{C}_{n ‐ 1} \\ Δ t {C}_{n ‐ 1} \\ - Δ t\end{matrix} ]$$

$$\hat{p} ( t + 1 ) = [ \begin{matrix}{\hat{p}}_{1} \\ {\hat{p}}_{2} \\ {\hat{p}}_{3}\end{matrix} ] = [ \begin{matrix}1 \\ α \\ α β\end{matrix} ]$$

$$k ( t + 1 ) = \frac{P ( t ) r ( t )}{λ + {r}^{T} ( t ) P ( t ) r ( t )}$$

$$P ( t + 1 ) = {λ}^{- 1} P ( t ) - k ( t + 1 ) {r}^{T} ( t ) {λ}^{- 1} P ( t )$$

$${\hat{y}}_{m} ( t + 1 ) = {r}^{T} ( t ) \hat{p} ( t )$$

$$\hat{p} ( t + 1 ) = \hat{p} ( t ) + k ( t + 1 ) ⌈ {y}_{s} ( t + 1 ) - {\hat{y}}_{m} ( t + 1 ) ]$$

With initialization of:

$$P ( {t}_{0} ) = [ \begin{matrix}{P}_{0} & 0 & 0 \\ 0 & {P}_{0} & 0 \\ 0 & 0 & {P}_{0}\end{matrix} ] with {P}_{0} >> 1$$

$$\hat{p} ( {t}_{0} ) = [ \begin{matrix}1 \\ {α}_{0} \\ {α}_{0} {β}_{0}\end{matrix} ]$$

with α₀ and β₀ identified from manufacturer ageing information, or accelerated ageing tests done on this capacitor.

These algorithms may be implemented in a controller of the converter or a controller of the motor but may also be implemented in a remote control system of the motor or controller.

Concerning the motor drive model, such model may comprise performance criterion Pc, including, but not limited to, dc voltage oscillation amplitude and motor control quality.

The drive model is used to simulate the behavior of the converter for decreasing values of the capacitance of the capacitor 3. The motor drive model 130, 230 simulates different system conditions, system parameters, system input power supply and load to evaluate at least one performance criterion continuously according to decreasing capacitance values. When such a performance criterion goes under a limit which corresponds to a degraded working mode of the converter, the corresponding capacitance value defines said minimum acceptable capacitance Cₗᵢₘ.

As seen above, different system conditions comprise grid impedance values R_{dc} 5, L_{dc} 6 which are pre-defined in the drive model or set by the user and based on the application load profile and history or comprise grid impedance R_{dc} 5, L_{dc} 6, of a worst-case scenario, with maximum rated grid impedance and maximum loading.

The method may be improved through the use of the ESR 7 of the capacitor in the calculations.

The method may then comprise:
a. calculating a DC link capacitor ESR based on the measurements of the voltage vsrc and current isrc at a voltage source upstream of the DC link capacitor and the measurements of the voltage vdc and current idc downstream from said DC link capacitor measurements,
b. implementing a modified motor drive model 230 and capacitor model 260 considering said DC link capacitor ESR to calculate the minimum capacitance Cₗᵢₘ and the minimum ESR, ESRₗᵢₘ allowing controlled system stability,
c. determining an ESR curve ESR_{curve} of said capacitor, and
d. calculating 220 the time difference between the actual capacitance and the forecasted minimum capacitance Cₗᵢₘ together with the difference between the actual ESR and the forecasted minimum ESR ESRₗᵢₘ, to estimate the remaining useful life of said capacitor considering the first occurrence of one of said minimum capacitance and minimum ESR.

The method may comprise tracking the capacitance value through a capacitance observer 400 activated during transient conditions.

The following dc-link model can be used to design an observer that tracks the capacitance value:

$$\frac{{di}_{src}}{dt} = - \frac{{R}_{dc}}{{L}_{dc}} {i}_{src} + \frac{1}{{L}_{dc}} {v}_{src} - \frac{1}{{L}_{dc}} {v}_{dc}$$

$$\frac{{dv}_{dc}}{dt} = \frac{1}{{C}_{dc}} {i}_{src} - \frac{P}{{C}_{dc} {v}_{dc}}$$

$$\frac{{dC}_{dc}}{dt} = 0$$

The system is nonlinear, we can study the observability of the linearized system around equilibrium.

The observability condition is P₀≠ν_{dc0}i_{src0}. Note that in at equilibrium:

$${i}_{src 0} = \frac{{v}_{src 0} - {v}_{dc 0}}{{R}_{dc}}$$

$$and {P}_{src 0} = {v}_{src 0} {i}_{src 0} = {R}_{dc} {i}_{src 0}^{2} + {v}_{dc 0} {i}_{src 0} .$$

Then, the observability condition can be expressed as:

$${P}_{0} \neq {P}_{src 0} - {R}_{dc} {i}_{src 0}^{2}$$

The above inequality is not valid for DC-steady state. It is nevertheless valid during transient, and for sinusoidal (harmonic) steady state. Therefore, the above system is only observable during transient or sinusoidal (harmonic) steady state. With respect to the harmonic steady state, observations are possible using the ripple of the voltage V_{DC} in FIG. 1 but such observations need sampling means which are fast enough to sample said ripple.

Another approach considers the ESR, denoted r_{c}. The system becomes:

$$\frac{{di}_{src}}{dt} = - \frac{{R}_{dc} + {r}_{c}}{{L}_{dc}} {i}_{src} + \frac{{r}_{c}}{{L}_{dc}} {i}_{dc} + \frac{{v}_{src} - {v}_{c}}{{L}_{dc}}$$

$$\frac{{dv}_{c}}{dt} = \frac{{i}_{src} - {i}_{dc}}{{C}_{dc}}$$

$$\frac{{dC}_{dc}}{dt} = 0$$

$$\frac{{dr}_{c}}{dt} = 0$$

$${v}_{dc} = {v}_{c} + {r}_{c} ( {i}_{src} - {i}_{dc} )$$

Knowing that

$${i}_{dc} = \frac{{P}_{dc}}{{v}_{dc}} = \frac{P}{{v}_{c} + {r}_{c} ( {i}_{src} - {i}_{dc} )}$$

In this equation P_{dc}=i_{dc}·v_{dc}. P_{dc} is not measured but can be estimated directly knowing the losses ratio of the converter, and the output power Pₒᵤₜ of the converter. With the known curve LossRatio(Pₒᵤₜ)=Pₒᵤₜ/P_{dc}, then P_{dc}=iₒᵤₜ·vₒᵤₜ. LossRatio (Pₒᵤₜ). V_{dc} being known, we can also use LossRatio (iₒᵤₜ, vₒᵤₜ)=iₒᵤₜ/i_{dc} on the output current to estimate P_{dc}=iₒᵤₜ·v_{dc}·LossRatio(iₒᵤₜ).

When solving i_{dc} and replacing in the above equations, the system becomes highly nonlinear, and the linearization is tedious. To simplify, let's start with i_{dc} as an independent source. The system is still nonlinear, when linearized it becomes:

$$\frac{d}{dt} [ \begin{matrix}{i}_{src} \\ {v}_{c} \\ {C}_{dc} \\ {r}_{c}\end{matrix} ] = [ \begin{matrix}- \frac{{R}_{dc} + {r}_{c 0}}{{L}_{dc}} & - \frac{1}{{L}_{dc}} & 0 & \frac{{i}_{dc 0} - {i}_{src 0}}{{L}_{dc}} \\ \frac{1}{{C}_{dc 0}} & 0 & \frac{{i}_{dc 0} - {i}_{src 0}}{{C}_{dc 0}^{2}} & 0 \\ 0 & 0 & 0 & 0 \\ 0 & 0 & 0 & 0\end{matrix} ] [ \begin{matrix}{i}_{src} \\ {v}_{c} \\ {C}_{dc} \\ {r}_{c}\end{matrix} ] + [ \begin{matrix}\frac{1}{{L}_{dc}} & \frac{{r}_{c 0}}{{L}_{dc}} \\ 0 & - \frac{1}{{C}_{dc 0}} \\ 0 & 0\end{matrix} ] [ \begin{matrix}{v}_{src} \\ {i}_{dc}\end{matrix} ]$$

$$y = {v}_{dc} = [ \begin{matrix}{r}_{c 0} & 1 & 0 & {i}_{src 0} - {i}_{dc 0}\end{matrix} ] [ \begin{matrix}{i}_{src} \\ {v}_{c} \\ {C}_{dc} \\ {r}_{c}\end{matrix} ] + [ \begin{matrix}0 & - {r}_{c}\end{matrix} ] [ \begin{matrix}{v}_{src} \\ {i}_{dc}\end{matrix} ]$$

The observability condition is i_{src0}≠i_{dc0}, which is not the case in steady state. Therefore, the system in only observable in transient operation or sinusoidal (harmonic) steady-state.

To observe the value of r_{c}, such value needs to be added to the state vector.

i_{dc}=P/ν_{dc} is not directly measured, but is known from the measurement of ν_{dc} and the indirect measurement of the power P using internal control signals, ex: P=νₐiₐ+ν_{b}i_{b}+ν_{c}i_{c}+Pₗₒₛₛ^{inv}

where a, b, c are the three phases of the motor.

P=i_{dc}·v_{dc}, P is not measured, but can be estimated directly knowing the losses ratio of the converter, and the output power P_{DC} at the source side. With the known curve LossRatio(P_{dc})=P_{dc}/P, then P=i_{src}·v_{src}·LossRatio (P_{dc}).

In this specific application, the grid input voltage is measured, and the dc-link parameters (dc-choke) are known, ν_{c} is the capacitor voltage. r_{c} is the ESR.

Observability study shows that the system is also observable during transients which allows to estimate the capacitance of the capacitor 3.

This permits to calculate the temperature of said capacitor using a comparison of a measured capacitance and a capacitor C_{ageing} resulting of the capacitor curve C_{curve} obtained after the curve initialization 100.

In building the ageing curve for the capacitor, the values of C outside the curve are rejected. However, in use, the values outside the curve are used to give a temperature value using the supplier curve ΔC/Δtemp.

The invention is not limited to the above description and in particular the embodiment of FIG. 5 may be modified to incorporate the ESR calculation of FIG. 3.

1. A method to estimate a remaining of useful life of a DC link capacitor of a converter through determination of a minimum value Cₗᵢₘ of its capacitance C under which performances of the converter are considered as insufficient comprising:
implementing a real time model comprising a motor drive model and a capacitor model using decreasing capacitor values to calculate a forecasted minimum capacitance Cₗᵢₘ sufficient for keeping at least one of DC voltage ripple, motor current ripple, speed ripple or torque ripple under a specified value;
calculating a time difference between a time T_{actual}, for which the capacitor has an estimated capacitance based on an ageing curve C_{curve}, and a time Tₗᵢₘ for which the capacitor will have the forecasted minimum capacitance Cₗᵢₘ, with the use of an ageing curve C_{curve} of said capacitor and estimating the remaining useful life of said capacitor T_{actual}−Tₗᵢₘ.

2. The method according to claim 1 comprising initializing said ageing curve through capacitance calculation of estimated values of said DC link capacitor during an initialization phase to provide an initial part of said ageing curve C_{curve} and calculating a remainder of said ageing curve C_{curve} using ageing characteristics of said capacitor.

3. The method according to claim 2 wherein said capacitance calculation comprises:
measuring of a voltage v_{src} and a current i_{src} at a voltage source upstream of the DC link capacitor;
measuring a voltage v_{dc} downstream from said DC link capacitor and either measuring a current i_{dc} or measuring an output power Pₒᵤₜ and calculating an input power P_{dc}, which is equal to an output power Pₒᵤₜ plus converter losses Pₗₒₛₛ, downstream from said DC link capacitor;
calculating an estimation of a capacitance value Ĉ of said capacitor based on said voltage v_{dc} downstream from said DC link capacitor, current i_{dc} or input power P_{dc}.

4. The method according to claim 3, wherein Pₗₒₛₛ is identified through a known function Pₗₒₛₛ=f(Pₒᵤₜ).

5. The method according to claim 1, wherein said motor drive model comprises performance criterion Pc, including, but not limited to, dc voltage oscillation amplitude and motor control quality and wherein said motor drive model is simulated for different system conditions, system parameters and system input power supply and load to evaluate such performance criterion continuously according to decreasing capacitance values and define said minimum acceptable capacitance Cₗᵢₘ.

6. The method according to claim 5 wherein said different conditions comprise grid impedance values R_{dc}, L_{dc} which are pre-defined in the drive model or predefined by the user and based on the application load profile and history.

7. The method according to claim 6, wherein said different conditions comprise grid impedance R_{dc}, L_{dc}, corresponding to a usual loading or grid impedance R_{dc}, L_{dc} of a worst-case scenario, with maximum rated grid impedance and maximum loading.

8. The method according to claim 1, comprising further comprising:
calculating an ESR of said DC link capacitor based on said measurements,
implementing a modified motor drive model and capacitor model considering said ESR of said DC link capacitor to calculate the minimum capacitance Cₗᵢₘ and the minimum ESR ESRₗᵢₘ allowing controlled system stability,
determining an ESR curve ESR_{curve} of said capacitor, and
calculating the time difference between the actual capacitance and the forecasted minimum capacitance Cₗᵢₘ together with the difference between the actual ESR and the forecasted minimum ESR ESRₗᵢₘ, to estimate the remaining useful life of said capacitor considering the first occurrence of one of said minimum capacitance and minimum ESR.

9. The method according to claim 1, wherein said ageing curve C_{curve} is based on a capacitor ageing model of the form Cₐ(t)=e^{αt}+β.

10. The method according to claim 2, further comprising tracking a capacitance value C_{actual} through a capacitance observer activated during transient conditions of the operation of the converter.

11. The method according to claim 10 comprising calculating temperature of said capacitor using a comparison of said capacitance value C_{actual} and a capacitor C_{ageing} resulting of the capacitor curve C_{curve} obtained after the curve initialization.

12. The method according to claim 1, further comprising tracking a capacitance value C_{actual} through a capacitance observer activated during transient conditions of the operation of the converter.
